(19) United States
(12) Patent Application Publication
(10) Pub. No.: US 2024/0311525 A1
(43) Pub. Date: Sep. 19, 2024

(54) PHYSICAL MODEL GENERATION APPARATUS, CONTROL METHOD, AND COMPUTER-READABLE STORAGE MEDIUM

(71) Applicant: NEC Corporation, Minato-ku, Tokyo (JP)

(72) Inventors: Taniya SINGH, Tokyo (JP); Masafumi Watanabe, Singapore (SG)

(73) Assignee: NEC Corporation, Minato-ku, Tokyo (JP)

(21) Appl. No.: 18/283,059

(22) PCT Filed: Mar. 23, 2021
(86) PCT No.: PCT/JP2021/011935

§ 371 Date: Sep. 20, 2023

(51) Int. Cl. G06F 30/17

(52) U.S. Cl. CPC G06F 30/17

(57) ABSTRACT

A physical model generation apparatus (2000) acquires architecture information (10), state information (20), and template information (30). The architecture information (10) describes physical components (52) included in a target control system (50), and connections (54) for each physical component (52). The state information (20) describes associations between a state of the physical component and one or more working connections through which signals are transferred in the corresponding state. The template information (30) describes associations between a behavior template and a connection condition. The behavior template describes behaviors that are common to the physical components (52) whose working connections satisfy the connection condition corresponding thereto. The physical model generation apparatus (2000) generates a physical model (40) that includes, for each physical component (52), behavior information (42) that describes behaviors of the physical component (52) for each of its possible states.

### TECHNICAL FIELD

The present disclosure generally relates to a physical model of a control system.

### BACKGROUND ART

A physical model of a control system is used for various reasons. The control system comprises physical components such as sensors, actuators, controllers, and so on. For example, various simulations are run on the physical model to perform security risk assessment for the control system.

PTL 1 discloses a technique related to an automatic generation of a physical model. Specifically, PTL1 discloses to acquire an input model that describes a nominal mode of operation for a system, and generate an augmented model that describes a non-nominal mode of operation for the system.

### CITATION LIST

### Patent Literature

PTL 1: EP2838016A

### SUMMARY OF INVENTION

### Technical Problem

The technique disclosed by PTL1 assumes that the input model is prepared in advance. Thus, it is considered that engineers have to manually generate a model representing a nominal mode of operation for a system. An objective of the present disclosure is to provide a technique for facilitating the generation of a physical model of a control system.

### Solution to Problem

The present disclosure provides a physical model generation apparatus comprising at least one processor and a memory storing instructions. The at least one processor is configured to execute the instructions to: acquire architecture information that describes a plurality of physical components included in a target control system, and one or more connections with another physical component for each of the plurality of the physical components; acquire, for each of the plurality of the physical components described in the architecture information, state information that describes one or more associations between a state of the physical component and one or more working connections that are the connections through which signals are transferred in the state corresponding thereto; acquire template information that describes a plurality of associations between a behavior template and a connection condition, the behavior template describing one or more behaviors that are common to the physical components whose working connections satisfy the connection condition corresponding thereto; generate, for each of the plurality of the physical components described in the architecture information, behavior information that describes one or more behaviors of the physical component for each of the states of the physical component based on the architecture information, the state information, and the template information, thereby generating a physical model of the target control system that includes the behavior information of each of the plurality of the physical components included in the target control system.

The present disclosure provides a control method performed by a computer. The control method comprises: acquiring architecture information that describes a plurality of physical components included in a target control system, and one or more connections with another physical component for each of the plurality of the physical components; acquiring, for each of the plurality of the physical components described in the architecture information, state information that describes one or more associations between a state of the physical component and one or more working connections that are the connections through which signals are transferred in the state corresponding thereto; acquiring template information that describes a plurality of associations between a behavior template and a connection condition, the behavior template describing one or more behaviors that are common to the physical components whose working connections satisfy the connection condition corresponding thereto; generating, for each of the plurality of the physical components described in the architecture information, behavior information that describes one or more behaviors of the physical component for each of the states of the physical component based on the architecture information, the state information, and the template information, thereby generating a physical model of the target control system that includes the behavior information of each of the plurality of the physical components included in the target control system.

The present disclosure provides a computer-readable storage medium storing a program that causes a computer to perform each step of the above-mentioned control method.

### Advantageous Effects of Invention

According to the present disclosure, it is possible to provide a technique for facilitating the generation of the physical model of the control system.

### BRIEF DESCRIPTION OF DRAWINGS

FIG. 1 is a block diagram illustrating an example of a functional configuration of a physical model generation apparatus according to the first example embodiment.

FIG. 2 is a block diagram illustrating an example of the hardware configuration of a computer realizing the physical model generation apparatus.

FIG. 3 is a flow diagram illustrating a flow of processes performed by the apparatus of the 1st example embodiment.

FIG. 4 illustrates an example architecture of the target control system.

FIG. 5 illustrates an example of the architecture information in a table format.

FIG. 6 illustrates an example of the state information in a table format.

FIG. 7 illustrates an example of the connection conditions.

FIG. 8 illustrates an example of the template information in a table format.

FIG. 9 illustrates an example of the physical model in a table format.

FIG. 10 is a flow diagram illustrating an example flow of concrete processes to generate the behavior information.

FIG. 11 illustrates the architecture of the target control system of the second example.

FIG. 12A illustrates the architecture information of the target control system of the second example.

FIG. 12B illustrates the architecture information of the target control system of the second example.

FIG. 13 illustrates the state information that describes possible states of push buttons included in the target control system of the second example.

FIG. 14 illustrates the state information that describes possible states of operators included in the target control system of the second example.

FIG. 15A illustrates the physical model generated for the target control system of the second example.

FIG. 15B illustrates the physical model generated for the target control system of the second example.

### DESCRIPTION OF EMBODIMENTS

Example embodiments according to the present disclosure will be described hereinafter with reference to the drawings. The same numeral signs are assigned to the same elements throughout the drawings, and redundant explanations are omitted as necessary. In addition, predetermined information (e.g., a predetermined value or a predetermined threshold) is stored in advance in a storage device to which a computer using that information has access unless otherwise described.

### FIRST EXAMPLE EMBODIMENT

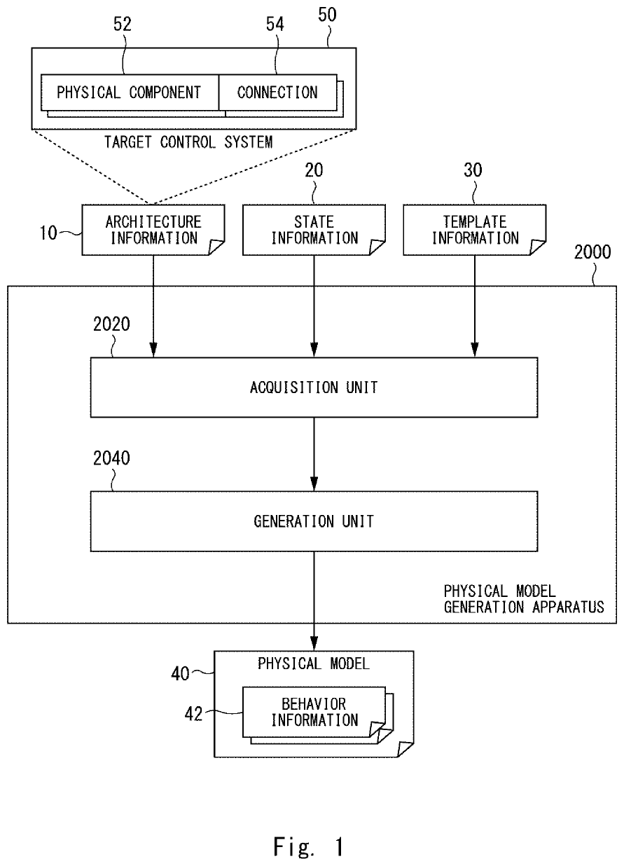

FIG. 1 is a block diagram illustrating an example of a functional configuration of a physical model generation apparatus 2000 according to the first example embodiment. The physical model generation apparatus 2000 generates a physical model 40 of a control system to be modeled (hereinafter, target control system 50). The target control system 50 includes a plurality of physical components 52. The physical component 52 may include a sensor, an indicator, an actuator, a controller, and other pieces of equipment. For example, a conveyor belt system may include push buttons, indicators, a controller, and a conveyor belt. The controller may include a Programmable Logic Controller (PLC) and a Distributed Control System (DCS) that monitors and controls other physical components 52.

The physical model 40 is required to describe behaviors of each physical component 52 of the target control system 50. However, it is time consuming to manually define behaviors of each physical component 52. In particular, the physical components 52 may have multiple states, such as working or fault, and their behaviors may depend on their state. This fact makes a manual definition of the behaviors of the physical components 52 more time consuming.

Thus, the physical model generation apparatus 2000 automatically generates a physical model 40 that describes behaviors of each physical component 52 based on possible states of each physical component 52 and template information of behaviors. To do so, the physical model generation apparatus 2000 may include an acquisition unit 2020 and a generation unit, and these units operate as follows.

The acquisition unit 2020 acquires architecture information 10 that describes an architecture of the target control system 50. Specifically, the architecture information 10 describes each of the physical components 52 that are included in the target control system 50. In addition, the architecture information 10 describes, for each of the physical components 52, one or more connections 54 that are the connections between that physical component 52 and another one.

The acquisition unit 2020 also acquires state information 20 for each of the physical components 52. The state information 20 describes possible states of one or more of the physical components. Note that the possible states of the physical component may depend on its type, such as “controller” or “conveyor belt”. Thus, the state information 20 may be defined for each type of the physical components. The type of each physical component 52 may be shown in the architecture information 10. The physical model generation apparatus 2000 acquires the state information 20 for each type of the physical components 52.

The state information 20 also shows, for each of the states of the physical component, one or more connections of the physical component through which signals are transferred in that state. Hereinafter, the connection of the physical component through which signals are transferred in a certain state is described as being “a working connection” corresponding to that state. Thus, for example, the state information 20 shows, for each type of the physical component, associations between the state of the physical component and one or more working connections of the physical component in the associated state.

Based on the architecture information 10 and the state information 20, the physical model generation apparatus 2000 can recognizes the possible state of each of the physical components 52 in the target control system 50. In addition, the physical model generation apparatus 2000 can also recognize which connection 54 of each physical component 52 is used to send or receive signals in each state.

The acquisition 2020 also acquires template information 30, which describes templates of behaviors of the physical components. Specifically, the template information 30 includes a behavior template for each connection condition. In other words, associations between the behavior template and the connection condition are included in the template information 30.

The connection condition indicates one or more conditions regarding one or more working connections. The behavior template describes one or more behaviors that are common to the physical components whose working connections satisfy the connection conditions corresponding to that behavior template. This means that the template information 30 shows one or more behaviors of the physical components 52 for each set of the conditions regarding the working connections of the physical components 52.

By using the architecture information 10, the state information 20 and the template information 30, the generation unit 2040 generates a physical model 40 that includes behavior information 42 for each physical component 52 of the target control system 50. The behavior information 42 of the physical component 52 describes behaviors of that physical component 52 for each state of that physical component 52 shown in the state information 20. The behaviors of the physical component 52 in the state are determined based on the behavior template corresponding to the connection conditions that are satisfied by the working connections of that physical component 52 in that state.

### Example of Advantageous Effect

The physical model generation apparatus 2000 generates the physical model 40 of the garget control system 50 that represents behaviors of each physical component 52. The physical model 40 is generated using the architecture information 10, the state information 20, and the template information 30. Since the physical model generation apparatus 2000 does not require users to prepare a physical model that represents a nominal mode of operation for the target control system 50, it is easy for users to generate the physical model of the target control system 50.

In addition, by using the architecture information 10, the state information 20, and the template information 30, it is possible to obtain a template of behaviors for each combination of the physical component 52 and its state. Thus, the physical model generation apparats 2000 can determine behaviors for each of multiple states of the physical model 52, thereby generating the physical model 40 that shows behaviors for each of multiple states of the physical component 52.

Hereinafter, the detail of the physical model generation apparatus 2000 of the 1st example embodiment will be described.

### Example of Hardware Configuration

The physical model generation apparatus 2000 may be realized by one or more computers. Each of the one or more computers may be a special-purpose computer manufactured for implementing the physical model generation apparatus 2, or may be a general-purpose computer like a personal computer (PC), a server machine, or a mobile device.

The physical model generation apparatus 2000 may be realized by installing an application in the computer. The application is implemented with a program that causes the computer to function as the physical model generation apparatus 2000. In other words, the program is an implementation of the functional units of the physical model generation apparatus 2000.

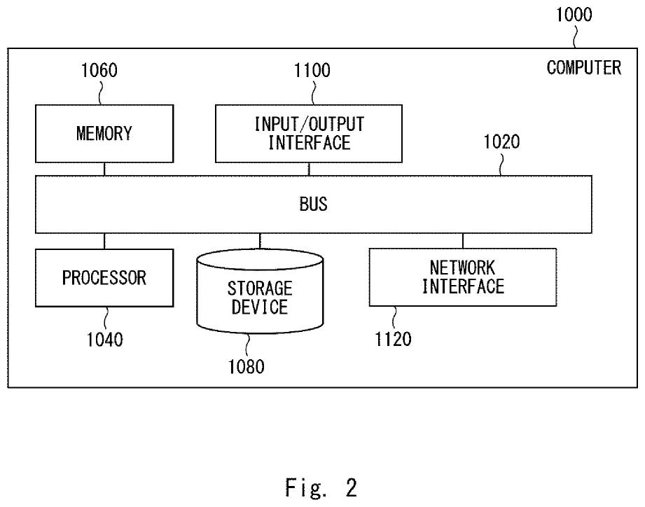

FIG. 2 is a block diagram illustrating an example of the hardware configuration of a computer 1000 realizing the physical model generation apparatus 2000. In FIG. 2, the computer 1000 includes a bus 1020, a processor 1040, a memory 1060, a storage device 1080, an input/output (I/O) interface 1100, and a network interface 1120.

The bus 1020 is a data transmission channel in order for the processor 1040, the memory 1060, the storage device 1080, and the I/O interface 1100, and the network interface 1120 to mutually transmit and receive data. The processor 1040 is a processer, such as a CPU (Central Processing Unit), GPU (Graphics Processing Unit), or FPGA (Field-Programmable Gate Array). The memory 1060 is a primary memory component, such as a RAM (Random Access Memory) or a ROM (Read Only Memory). The storage device 1080 is a secondary memory component, such as a hard disk, an SSD (Solid State Drive), or a memory card. The I/O interface 1100 is an interface between the computer 1000 and peripheral devices, such as a keyboard, mouse, or display device. The network interface 1120 is an interface between the computer 1000 and a network. The network may be a LAN (Local Area Network) or a WAN (Wide Area Network). The storage device 1080 may store the program mentioned above. The CPU 1040 executes the program to realize each functional unit of the physical model generation apparatus 2000.

The hardware configuration of the computer 1000 is not restricted to that shown in FIG. 2. For example, as mentioned-above, the physical model generation apparatus 2000 may be realized by plural computers. In this case, those computers may be connected with each other through the network.

### <Flow of Processes>

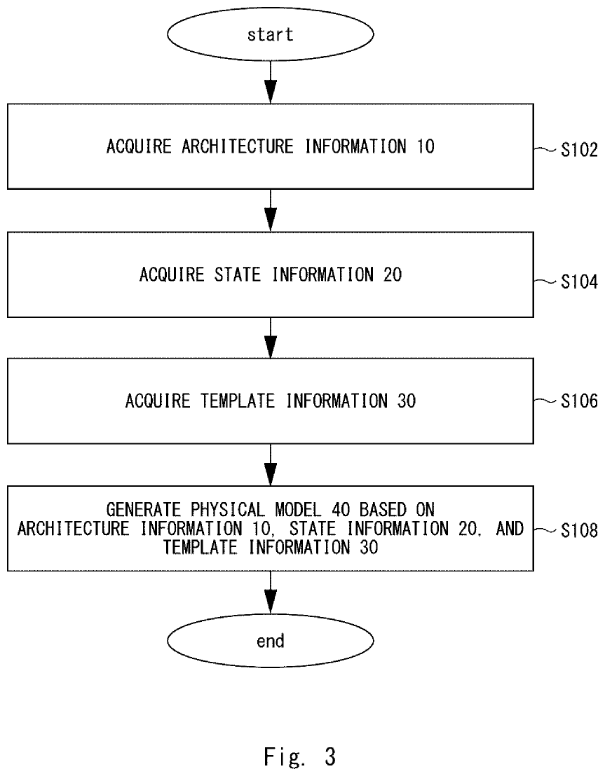

FIG. 3 is a flow diagram illustrating a flow of processes performed by the physical model generation apparatus 2000 of the 1st example embodiment. The acquisition unit 2020 acquires the architecture information 10 (S102). The acquisition unit 2020 then acquires the state information 20 for each of the physical components 52 (S104) The acquisition unit 2020 next acquires the template information 30 (S106). The generation unit 2040 generates a physical model 40 that includes behavior information 42 for each physical component 52 of the target control system 50.

Note that the flow of processes performed by the physical model generation apparatus 2000 is not restricted to that shown in FIG. 3. For example, each information item may be acquired at an arbitrary timing as long as it is acquired before it is used. For example, the template information 30 may be acquired before the state information 20 is acquired.

### <Acquisition of Architecture Information: S102>

The acquisition unit 2020 acquires the architecture information 10 (S102). The architecture information 10 describes the architecture of the target control system 50. Specifically, the architecture information 10 describes associations of the physical components 52 that constitute the target control system 50 and the connections 54 that connect the physical component 52 to another physical component 52.

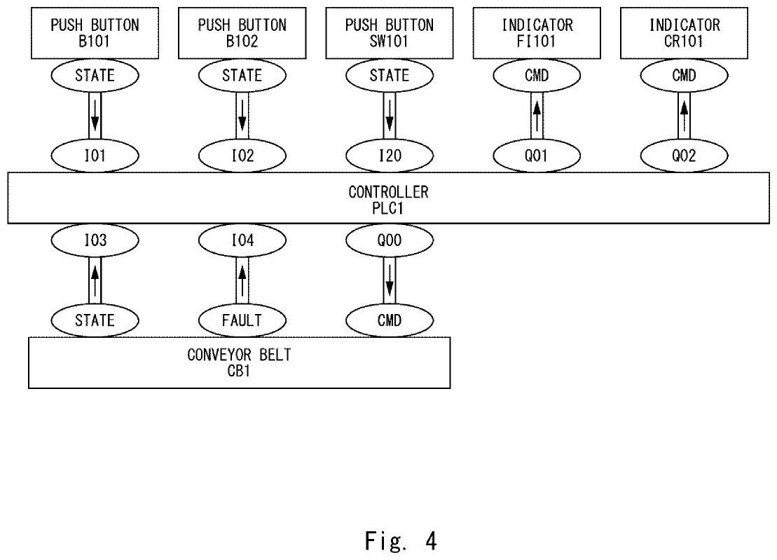

FIG. 4 illustrates an example architecture of the target control system 50. This target control system 50 includes seven physical components: three push buttons named “B101”, “B102”, and “SW101”, respectively; two indicators named “FI101” and “CR101”, respectively; a conveyor belt “CB1”; and a controller “PLC1”. In FIG. 4, each oval object represents a port through which the physical component 52 is connected with another one. In addition, an arrow represents a flow of signals. For example, the push button B101 has an output port named “STATE”, and this output port connects the push button B101 to the controller PLC1 through an input port of the controller PLC1 named “101”.

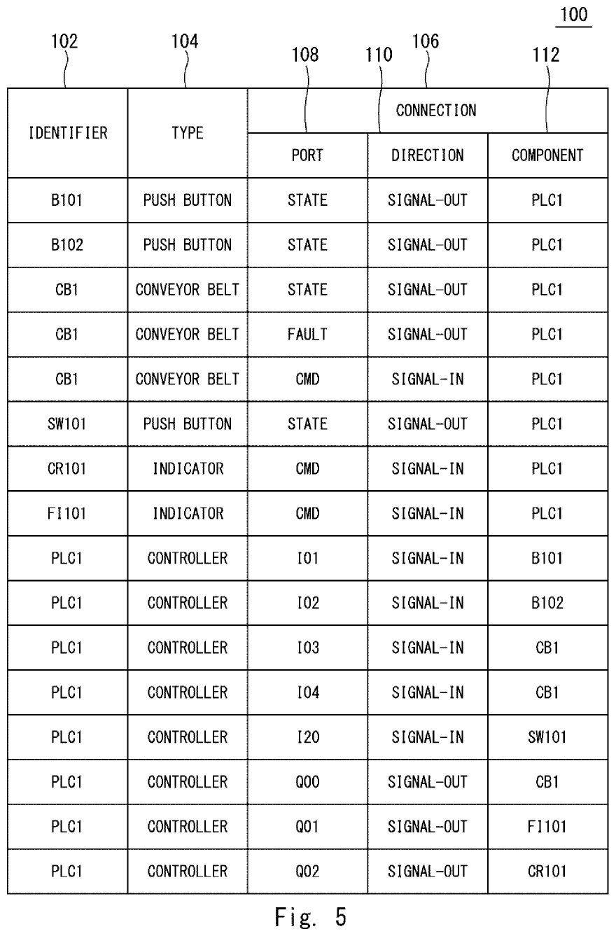

FIG. 5 illustrates an example of the architecture information 10 in a table format. A table 100 shown in FIG. 5 is an example of the architecture information 10, and shows the architecture of the target control system 50 illustrated in FIG. 4. The table 100 includes columns named “identifier 102”, “type 104”, and “connection 106”. The feature of the physical component 52 is indicated by one or more rows of the table 100.

The value of the identifier 102 indicates the identifier of the corresponding physical component 52. The value of the type 104 indicates the type of the physical component 52. For example, the first row of the table 100 in FIG. 5 shows that the target control system 50 includes the physical component 52 whose identifier is “B101” and whose type is “PUSH BUTTON”. The values of the connection 106 indicate one of the connections 54 that connects the physical component 52 to another one.

The connection 106 is further divided into columns named “port 108”, “direction 110”, and “component 112”. The value of the port 108 indicates the identifier of a port of the physical component 52. For example, the first row of the table 100 in FIG. 5 shows that the physical component B101 has the connection 54 that has a port named “STATE”.

The value of the direction 110 indicates the direction of the connection 54. Specifically, the value “SIGNAL-OUT” of the direction 110 indicates that the port 108 is an output port, and signals are output from the physical component 52 through that port. On the other hand, the value “SINGNAL-IN” of the direction 110 indicates that the port 108 is an input port, and signals are input to the physical component 52 through that port. For example, the first row of the table 100 in FIG. 5 shows that the port STATE of the push button B101 is an output port.

The value of the component 112 indicates the other end of the connection 54. For example, the first row of the table 100 in FIG. 5 shows that the connection 54 connects the push button B101 to the controller PLC1.

There may be a variety of ways to acquire the architecture information 10. For example, the architecture information 10 to be acquired by the acquisition unit 2020 is stored in advance in a storage device to which the plant model generation unit 2000 has access. In this case, the acquisition unit 2020 reads the architecture information 10 out of that storage device. In another example, the acquisition unit 2020 may receive the architecture information 10 sent from an arbitrary device. In another example, the architecture information 10 is manually input to the physical model generation apparatus 2000 by a user, and the acquisition unit 2020 acquires the architecture information 10 input by the user.

### <Acquisition of State Information 20: S104>

The acquisition unit 2020 acquires the state information 20 for each of the physical components 52 (S104). The state information 20 describes possible states of each physical components 52. As described above, the possible states of the physical components 52 may depend on their respective types. For example, the target control system 50 whose architecture is shown in FIG. 5 has three push buttons, and their possible states may be the same as each other. Thus, the state information 20 may be created for each type of the physical component.

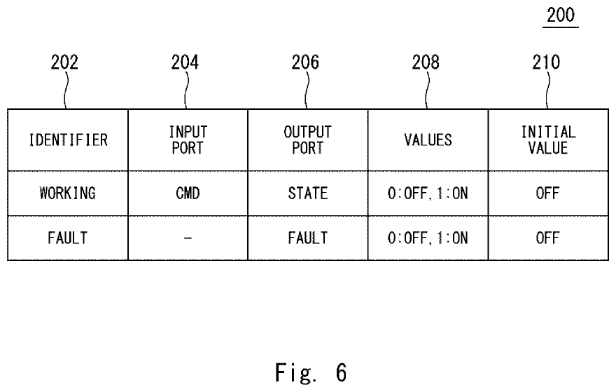

FIG. 6 illustrates an example of the state information 20 in a table format. A table 200 shown in FIG. 6 is an example of the state information 10 that describes possible states of the physical components 52 with the type CONVEYOR BELT.

The table 200 includes columns named “identifier 202”, “input port 204”, “output port 206”, “values 208” and “initial value 210”. Each row of the table 200 shows information regarding one of the possible states of the physical component 52 belonging to the type corresponding to that table 100.

The value of the identifier 202 indicates the identifier of the corresponding state. The value of the input port 204 indicates the identifier of the input port of the physical component 52 that is working in the state. Note that the term “working” here means that the port is used for communication. For example, the first row of the table 200 in FIG. 6 shows that, when a physical component 52 of the type CONVEYOR BELT is at the state WORKING, the input port CMD of that physical component 52 is working (in other words, used to receive signals sent from another physical component 52).

Similarly, the value of the output port 206 indicates the identifier of the output port of the physical component 52 that is working in the state. For example, the first row of the table 200 in FIG. 6 shows that, when a physical component 52 of the type CONVEYOR BELT is in the state WORKING, the output port STATE of that physical component 52 is working (in other words, used to transmit signals to another physical component 52).

The values 208 indicate possible values represented by the signals output from the physical components 52. For example, the first row of the table 200 in FIG. 6 shows that, when a physical component 52 of the type CONVEYOR BELT is in the state WORKING, its output signals may represent “OFF” or “ON”. Note that an expression [0: OFF, 1: ON] shown in the table 200 means that the values OFF and ON are handled as the 0th value and the 1st value, respectively.

The value of the initial value 210 indicates an initial value indicated by the signals output from the physical components 52. For example, the first row of the table 200 in FIG. 6 shows that, when a physical component 52 of the type CONVEYOR BELT is in the state WORKING, the initial value indicated by the output signals is OFF.

There may be a variety of ways to acquire the state information 20. For example, the state information 20 to be acquired by the acquisition unit 2020 is stored in advance in a storage device to which the plant model generation unit 2000 has access. In this case, the acquisition unit 2020 reads the state information 20 out of that storage device. In another example, the acquisition unit 2020 may receive the state information 20 sent from arbitrary device. In another example, the state information 20 is manually input to the physical model generation apparatus 2000 by a user, and the acquisition unit 2020 acquires the state information 20 input by the user.

Note that when the state information 20 is prepared for each type of the physical components, it is enough for the acquisition unit 2020 to acquire a single piece of the state information 20 for the plurality of the physical components 52 that are classified into the same type as each other. For example, in the case where the architecture of the target control system 50 is indicated by the table 100 of FIG. 5, the acquisition unit 2020 acquires the state information 20 of the type PUSH BUTTON once although there are three push buttons in the target control system 50.

### <Acquisition of Template Information 30: S106>

The acquisition unit 2020 acquires the template information 30 (S106). The template information 30 describes behaviors of the physical components 52 for each predefined connection condition. The connection condition is defined by a condition or a set of conditions regarding the connection 54 which is working. Here, before describing the template information 30 in detail, a further explanation on the connection condition will be described.

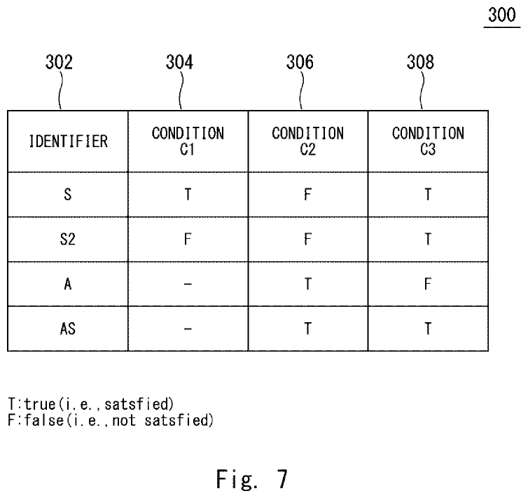

FIG. 7 illustrates an example of the connection conditions. A table 300 shown in FIG. 7 is an example of a set of the predefined connection conditions. The table 300 includes the columns named “identifier 302”, “condition C1”, ‘condition C2”, and condition C3”. The condition C1 indicates a condition where “the working connection has an input port and the other end of the working connection is not a controller”. The condition C2 indicates a condition where “the working connection has an input port and the other end of the working connection is a controller”. The condition C3 indicates a condition where “the working connection has an output port and the other end of the working connection is a controller”. Note that a set of conditions that is used to define the connection condition is not restricted to the conditions C1 to C3 described above.

Each connection condition is indicated by one of the rows of the table 300. The value of the identifier 302 indicates an identifier of the connection condition. The connection condition is indicated by the set of satisfactions or dissatisfactions of the conditions C1 to C3. For example, the connection condition named “S” represents the condition where “the conditions C1 and C2 are satisfied, whereas the condition C3 is not satisfied”.

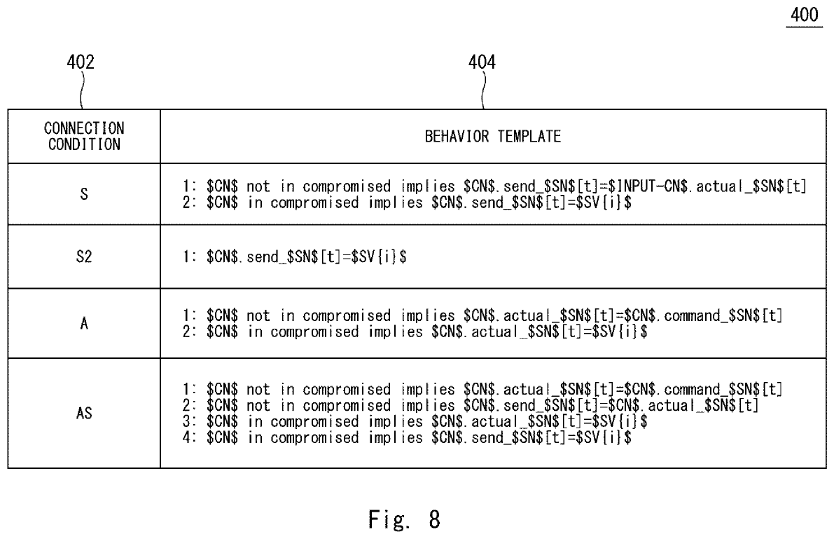

The template information 30 describes the set of behaviors of the physical components for each of the connection conditions, e.g., the connection conditions S, S2, A, and AS shown in FIG. 7. FIG. 8 illustrates an example of the template information 30 in a table format. A table 400 in FIG. 8 shows associations between the connection condition and the behaviors that are common to the physical components whose working connections satisfy the associated connection conditions.

The table 400 includes the columns named “connection condition 402” and “behavior template 404”. The value of the connection condition 402 indicates one of the predefined connection conditions. The value of the behavior template 404 indicates behaviors of the physical components whose working conditions satisfy the connection conditions. For example, the first row of the table 400 shows behaviors that are common to the physical components 52 whose working conditions satisfy the connection condition S, i.e., the conditions C1 and C3 are satisfied whereas the condition C2 is not satisfied.

Behaviors described by the behavior template 404 includes keywords to be replaced when generating the behavior information 40 using the table 400. By doing so, a description in the behavior template 404 that is common to multiple cases can be converted into a description that is specific to one case.

For example, the table 400 includes keywords “$CN$”, “$SN$”, “$SV{i}$”, and “$INPUT-CN$”. The keyword “$CN$” is used to describe an arbitrary physical component, and is replaced with the identifier of a concrete physical component. The keyword “$SNS” is used to describe an arbitrary state of a physical component, and is replaced with the identifier of a concrete state of the physical component.

Suppose that the identifier of the physical component 52 is CB1 and the state of that physical component 52 is WORKING. In this case, the phrase “$CN$.send_$SN$[t]” is converted into “CB1.send_WORKING[t]”. Note that CB1.send_WORKING[t] indicates the value sent by the physical component CB1 at the state WORKING at time t.

The keyword “$SV {i} $” is used to describe one or more values output from or input to a physical component in a certain state. When the state information 20 of the physical component 52 in the state shows one or more values output from that physical component 52 in the state, the keyword “$SV {i} $” is replaced with those values. On the other hand, when the state information 20 of the physical component 52 in the state shows no value output from that physical component 52 in the state, the keyword “$SV{i} $” is replaced with one or more values input to that physical component 52 (i.e., one or more values output from the other end of the connection 54).

Note that when the state information 20 shows multiple values output from the physical component in the state, multiple equations are generated and concatenated with each other using the term “or”.

Suppose that the identifier of the physical component 52 is CB1 and the state of that physical component 52 is WORKING. In addition, the state information 20 corresponding to the physical component CB1 shows values “0:OFF, 1:ON” for the state WORKING. In this case, the phrase “$CN$.send_$SN$[t]=$SV {i}” is converted into “CB1.send_WORKING[t]=OFF or CB1.send_WORKING[t]=ON”.

The keyword “$INPUT-CN$” is used to describe a physical component at the other end of the connection of the physical component 52 for which the behavior information 40 is generated.

The behavior template 404 shown in FIG. 7 includes behaviors of the physical components not only in the case where they are not compromised but also in the case where they are compromised. For example, the first line of the descriptions in the behavior template 404 in the first row of the table 400 shows the behavior of the physical components that are not compromised since the description includes the phrase “not in compromised”. On the other hand, the second line of the descriptions in the behavior template 404 in the first row of the table 400 shows the behavior of physical components that are compromised since the description includes the phrase “in compromised”. Since the behavior template 404 may also include the behaviors of compromised physical components, it is possible to simulate operations of the target control system 50 in a compromised state with the behavior information 40 that are generated using the template information 30. However, the behavior template 404 may not include behaviors of the compromised physical components.

There may be a variety of ways to acquire the template information 30. For example, the template information 30 to be acquired by the acquisition unit 2020 is stored in advance in a storage device to which the plant model generation unit 2000 has access. In this case, the acquisition unit 2020 reads the template information 30 out of that storage device. In another example, the acquisition unit 2020 may receive the template information 30 sent from an arbitrary device. In another example, the template information 30 is manually input to the physical model generation apparatus 2000 by a user, and the acquisition unit 2020 acquires the template information 30 input by the user.

### <Generation of Physical Model 40: S108>

The generation unit 2040 generates a physical model 40 that includes behavior information 42 for each physical component 52 of the target control system 50 based on the architecture information 10, the state information 20, and the template information 30 (S108). The behavior information 42 of the physical component 52 describes associations between the state of that physical component 52 and the behaviors of that physical component 52 in the associated state.

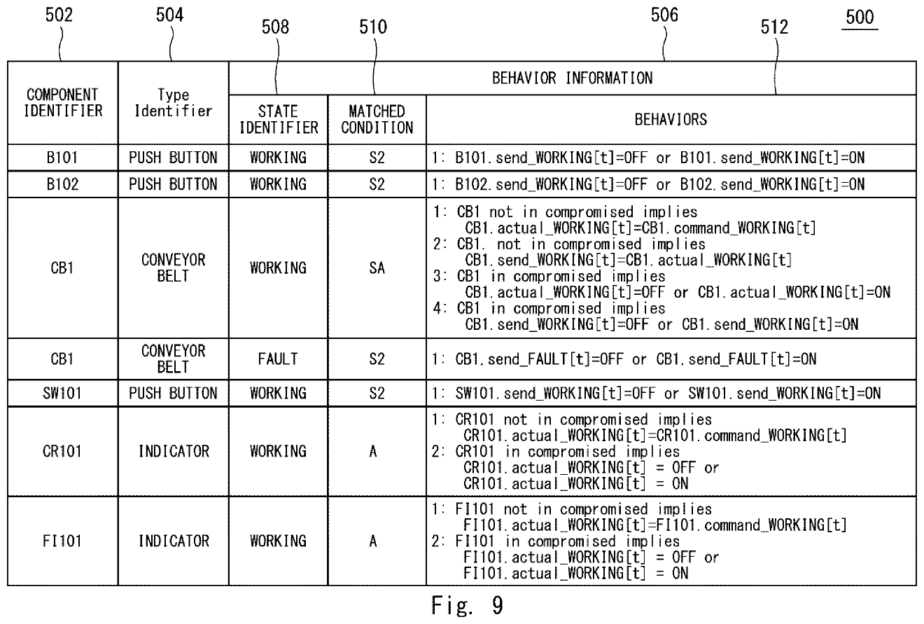

FIG. 9 illustrates an example of the physical model 60 in a table format. A table 500 shown in FIG. 9 is an example of the physical model 60 that is generated with the architecture information 10 shown in FIG. 5, the state information 20 shown in FIG. 6, and the template information 30 shown in FIG. 7.

The table 500 has columns named “component identifier 502”, “type identifier 504” and “behavior information 504”. The value of the component identifier 502 indicates the identifier of the physical component 52. The value of the type identifier 504 indicates the identifier of the type of the physical component 52. The value of the behavior information 504 indicates the behavior information 40 that is generated for the physical component 52.

The behavior information 506 is further divided into three columns named “state identifier 508”, “matched condition 510”, and “behaviors 512”. The value of the state identifier 508 indicates one of the possible states of the physical component 52. The value of the matched condition 510 indicates the connection condition that is satisfied by the working connection of the physical component 52 in the state. The value of the behaviors 512 indicates behaviors of the physical component 52 in the state that are determined based on the behavior template 404 corresponding to the connection condition shown in the matched condition 510.

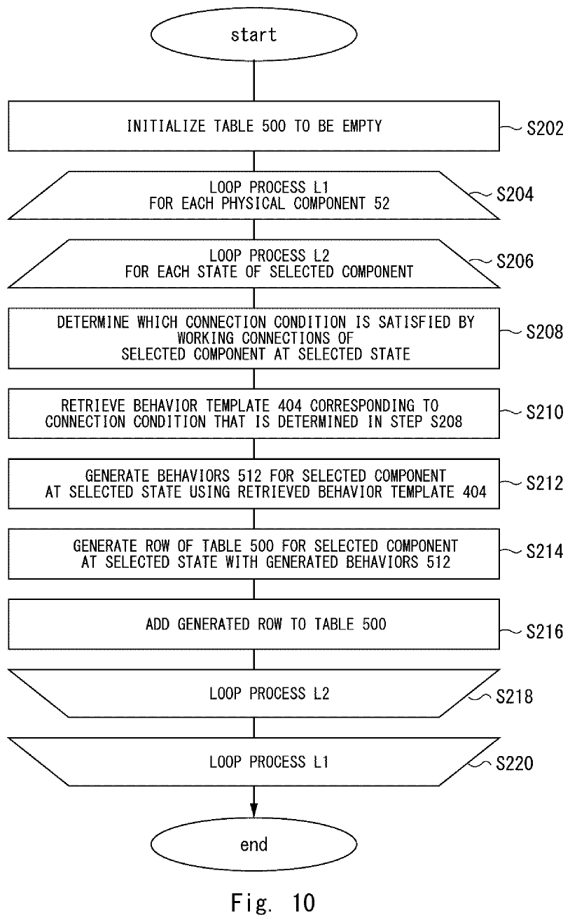

In order to generate the physical model 40, the generation unit 2040 refers to the architecture information 10, the state information 20, and the template information 30. A concrete way of generating the physical model 40 will be explained with reference to FIG. 10. FIG. 10 is a flow diagram illustrating an example of a flow of concrete processes to generate the behavior information 40.

The generation unit 2040 initializes the table 500 to be empty (S202). Steps S204 to S220 constitute a loop process L1, which is a set of processes to be performed for each of the physical components 52 shown in the architecture information 10. In Step S204, the generation unit 2040 determines whether the loop process L1 has been performed for all of the physical components 52. When it is determined that the loop process L1 has been performed for all of the physical components 52, the processes shown in FIG. 10 ends. This means that the generation of the physical model 40 has been finished. On the other hand, when it is determined that the loop process L1 has not been performed for all of the physical components 52, the generation unit 2040 selects one of the physical components 52 for which the loop process L1 is not performed yet. Note that the physical component 52 selected here is called “the selected component”.

Steps S206 to S218 constitute a loop process L2, which is a set of processes to be performed for each of the states of the selected component that is described by the state information 20 of the type corresponding to the selected component. In Step S206, the generation unit 2040 determines whether the loop process L2 has been performed for all of the possible states of the selected component. When it is determined that the loop process L2 has been performed for all of the possible states of the selected component, the loop process L2 ends. On the other hand, when it is determined that the loop process L2 has not been performed for all of the possible states of the selected component, the generation unit 2040 selects one of the possible states of the selected component for which the loop process L2 is not performed yet. Note that the state of the selected component selected here is called “the selected state”.

In Step S208, the generation unit 2040 determines which connection condition is satisfied by the working connections of the selected component at the selected state. Then, the generation unit 2040 retrieve the behavior template 404 corresponding to the connection condition 402 that is determined to be satisfied by the working connections of the selected component at the selected state (S210). The generation unit 2040 generate the behaviors 512 for the selected component at the selected state by replacing the keywords in the retrieved behavior template 404 (S212). Note that the way of replacing the keywords in the behavior template 404 was already mentioned above. The generation unit 2040 generates a row of the table 500 for the selected component at the selected state with the behaviors 512 generated in Step S212 (S214). The generation unit 2040 adds the row to the table 500 (S216). Step S218 is a termination of the loop process L2. Thus, Step S206 is performed next.

Suppose that the selected component is CB1 defined by the table 100 shown in FIG. 5, and that the selected state is WORKING. Regarding the state WORKING, the table 200 shows that CMD and STATE as the input port and the output port, respectively. Thus, the working connections of the physical component CB1 in the state WORKING are the connection 54 with the input port CMD and the connection 54 with the output port STATE.

The generation unit 2040 determines which connection condition is satisfied by the above-mentioned working connections. In this case, the working connections include the input port CMD, and this input port is connected to the controller PLC1. Thus, the condition C1 is satisfied, whereas the condition C2 is not satisfied. In addition, the working connections include the output port STATE, and this output port is connected to the controller PLC1. Thus, the condition C3 is satisfied. Table 300 shown in FIG. 7 shows that the connection condition with the conditions C1 and C3 being satisfied and with the condition C2 not being satisfied is the connection condition AS.

Since the connection condition AS is satisfied, the generation unit 2040 retrieves the behavior template 404 that is associated with the connection condition AS in the table 400. Then, the generation unit 2040 perform a replacement of the keywords in the retrieved behavior template 404.

In this case, the keywords “$CN$” and “SNS” are replaced with “CB1” and “WORKING”, respectively. Regarding the keyword “SV{i}”, there are two values “OFF” and “ON” that can be output from the physical component CB1 at the state WORKING. Thus, a single equation having the keyword “SV{i}” is converted into two equations: SV{i} is replaced with OFF in the first equation; and SV{i} is replaced with ON in the second equation. Then, these two equations are concatenated with the term “or”.

### <Output of Plant Model 40>

The generation unit 2040 outputs the plant model 40 in various manners. For example, the generation unit 2040 may put the plant model 40 into a storage device. In another example, the generation unit 2040 may output the plant model 40 to a display device so that the plant model 40 is displayed on that display device. In another example, the generation unit 2040 may send the plant model 40 to arbitrary apparatus.

There may be various application of the plant model 40. One of possible applications of the plant model 40 is a simulation of the target control system 50. The simulation using the plant model 40 enables, for example, a security risk assessment of the target control system 50 to be performed.

### <Another Example of Target Control System and Plant Model>

Here, another example of the target control system 50 and the plant model 40 generated for it will be described. The target control system 50 of the first example, whose architecture is shown in FIG. 4, includes no physical component 52 whose working connections satisfy the connection condition S shown in FIG. 8. Thus, the behavior template corresponding to the connection condition S is not used to the plant model 40 of the first example shown in FIG. 9. On the other hand, the target control system 50 of the second example described below includes physical components 52 whose working connections satisfy the connection condition S shown in FIG. 8. Thus, the plant model 40 of the second example includes the behaviors generated from the behavior template corresponding to the connection condition S.

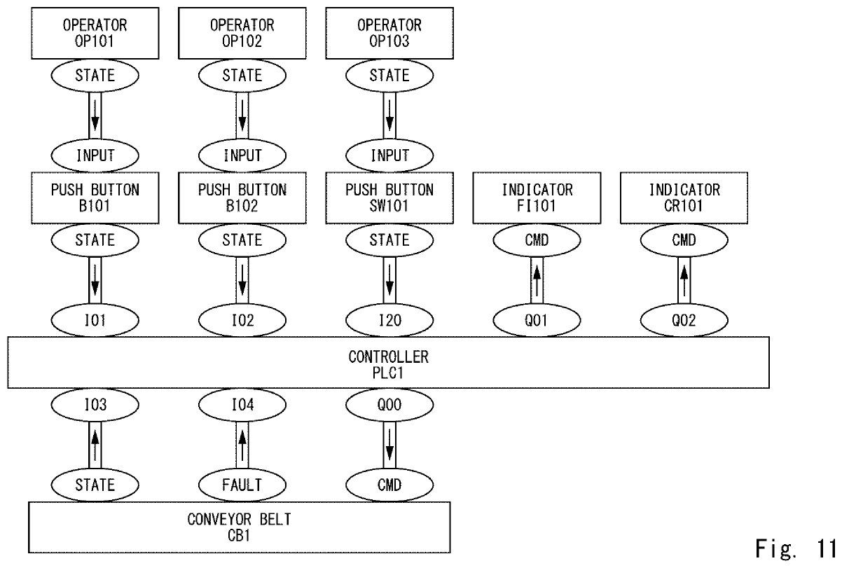

FIG. 11 illustrates the architecture of the target control system 50 of the second example. The target control system 50 of the second example is different from that of the first example in that it includes three operators named “OP101”, “OP102”, and “OP103” respectively. The physical component with the type “OPERATOR” is a person who operates another physical component such as a button. In order to simulate behaviors of operators, operators are treated as physical components in this example.

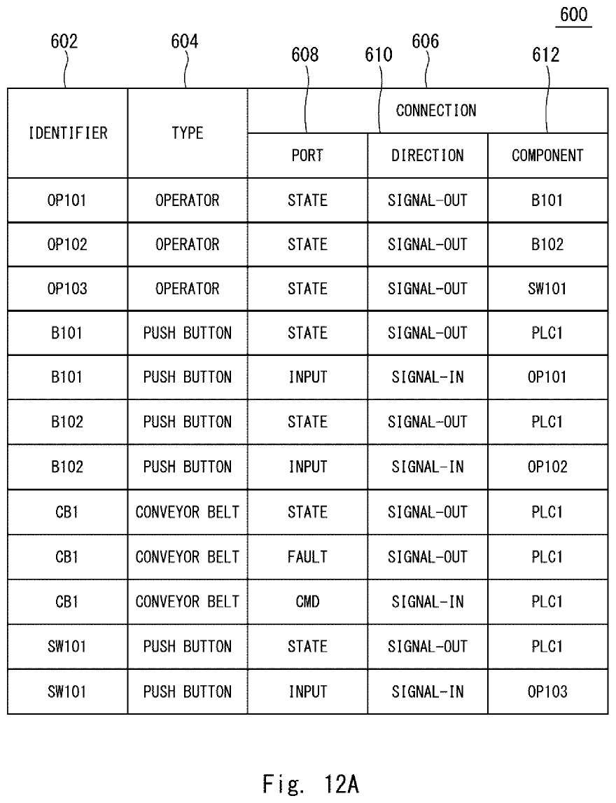

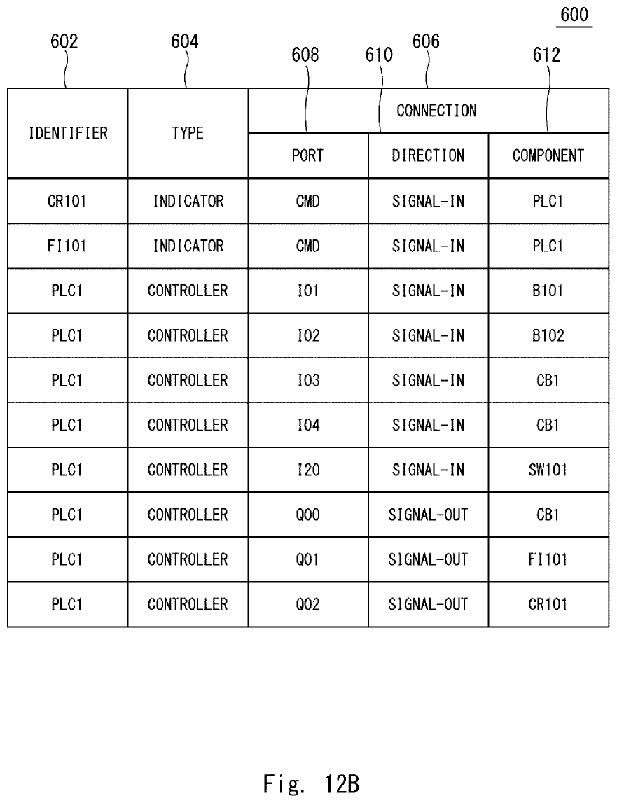

FIGS. 12A and 12B illustrate the architecture information 10 of the target control system 50 of the second example. A table 600 shown in FIG. 12 is different from the table 100 shown in FIG. 5 in that it includes additional rows defining the operators OP101, 102, and 103. In addition, in this example, a push button works in response to signals output from the operator connected therewith. Thus, each push button has an input port to receive the signals from the operator connected therewith.

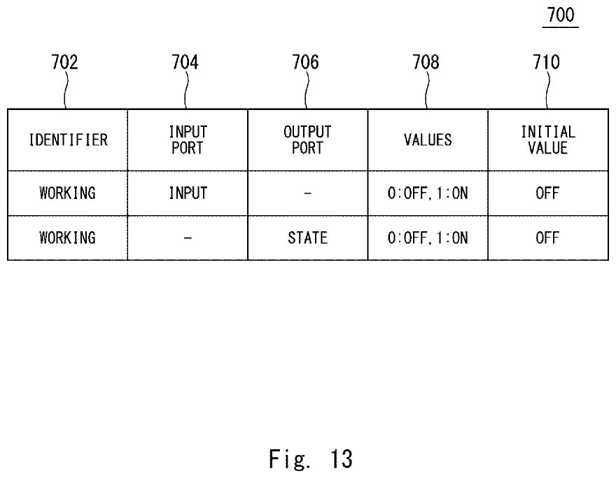

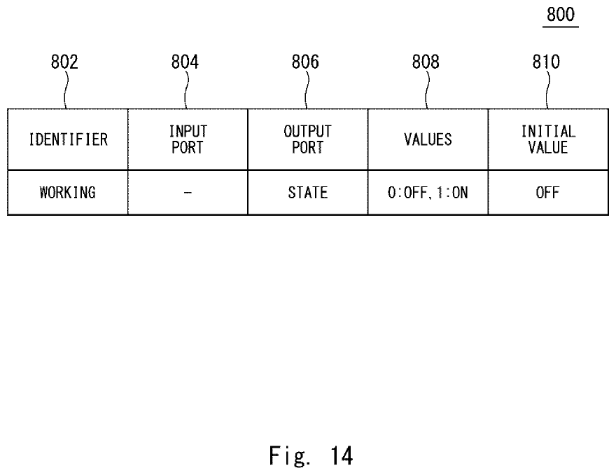

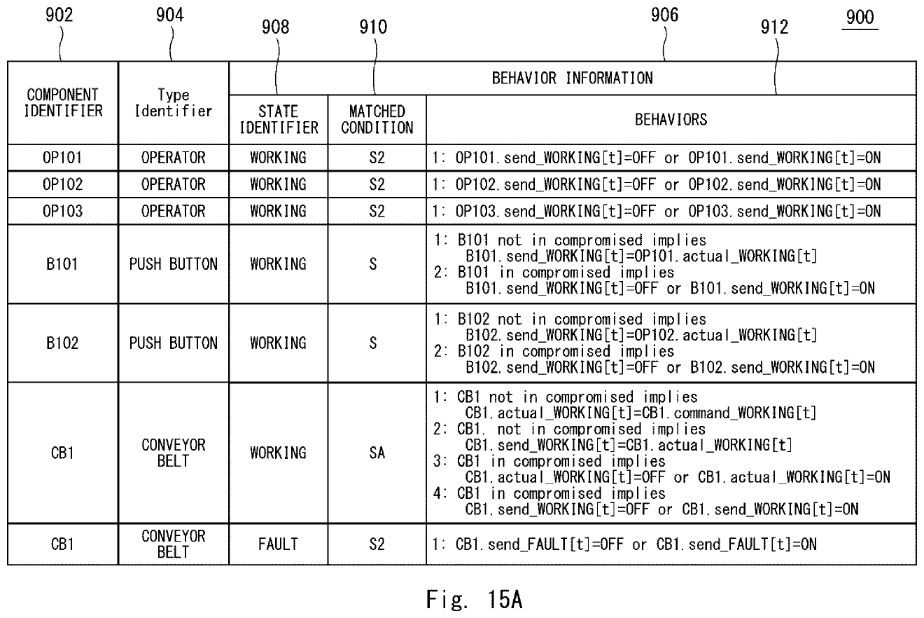

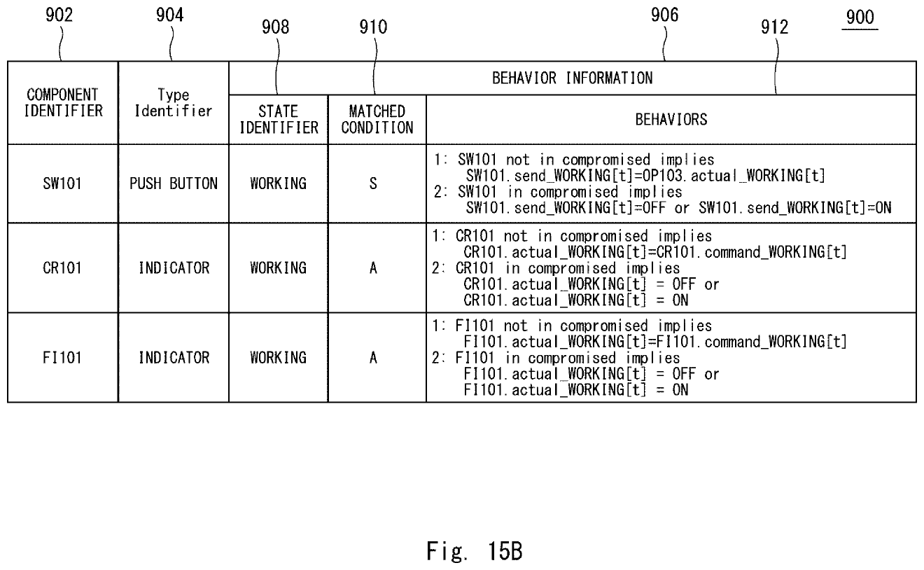

FIG. 13 illustrates the state information 20 that describes possible states of push buttons included in the target control system 50 of the second example. FIG. 14 illustrates the state information 20 that describes possible states of operators included in the target control system 50 of the second example. FIGS. 15A and 15B illustrate the physical model 60 generated for the target control system 50 of the second example.

In this example, the push buttons in the state WORKING have an input port connected to an operator (not to a controller) and an output port connected to a controller. Thus, the working connections of the push buttons in the state WORKING satisfy the connection condition S. As a result, the behaviors of the push buttons B101, B102, and SW101 are generated based on the behavior template corresponding to the connection condition S shown in FIG. 8.

Table 400 of FIG. 8 shows that the behavior template 404 corresponding to the connection condition S includes the keyword “$INPUT-CN$”. As described above, this keyword is used to describe a physical component at the other end of the connection of the physical component 52 for which the behavior information 40 is generated. For example, it is the operator OP101 that is connected to the input port of the push button B101 in the state WORKING, as shown in fifth row of table 600 in FIG. 12A. Thus, regarding the push button B101 in the state WORKING, the keyword $INPUT-CN$ in the behavior template is replaced with the identifier OP101, as shown in the fourth row of the table 900 in FIG. 15A.

While the present disclosure has been described above with reference to the embodiments, the present disclosure is not limited to the aforementioned description. Various changes that may be understood by one skilled in the art may be made on the configuration and the details of the present disclosure within the scope of the present disclosure.

In the aforementioned embodiments, the program(s) can be stored and provided to a computer using any type of non-transitory computer readable media. Non-transitory computer readable media include any type of tangible storage media. Examples of non-transitory computer readable media include magnetic storage media (such as flexible disks, magnetic tapes, hard disk drives, etc.), optical magnetic storage media (e.g., magneto optical disks), Compact Disc Read Only Memory (CD-ROM), CD-R, CD-R/W, and semiconductor memories (such as mask ROM, Programmable ROM (PROM), Erasable PROM (EPROM), flash ROM, Random Access Memory (RAM), etc.). The program(s) may be provided to a computer using any type of transitory computer readable media. Examples of transitory computer readable media include electric signals, optical signals, and electromagnetic waves. Transitory computer readable media can provide the program to a computer via a wired communication line (e.g., electric wires, and optical fibers) or a wireless communication line.

Note that the present disclosure is not limited to the above-described example embodiments and can be modified as appropriate without departing from the scope and spirit of the disclosure.

### <Supplementary Notes>

### (Supplementary Note 1)

A physical model generation apparatus comprising:
at least one processor; and
a memory storing instructions;
wherein the at least one processor is configured to execute the instructions to:
acquire architecture information that describes a plurality of physical components included in a target control system, and one or more connections with another physical component for each of the plurality of the physical components;
acquire, for each of the plurality of the physical components described in the architecture information, state information that describes one or more associations between a state of the physical component and one or more working connections that are the connections through which signals are transferred in the state corresponding thereto;
acquire template information that describes a plurality of associations between a behavior template and a connection condition, the behavior template describing one or more behaviors that are common to the physical components whose working connections satisfy the connection condition corresponding thereto;
generate, for each of the plurality of the physical components described in the architecture information, behavior information that describes one or more behaviors of the physical component for each of the states of the physical component based on the architecture information, the state information, and the template information, thereby generating a physical model of the target control system that includes the behavior information of each of the plurality of the physical components included in the target control system.

### (Supplementary Note 2)

The physical model generation apparatus according to supplementary note 1,
wherein the description of the behavior template includes: a first keyword to be replaced by an identifier of the physical component; the second keyword to be replaced by an identifier of the state of the physical component; or the third keyword to be replaced by one or more values output by the physical component, and
the generation of the behavior information for a physical component in a state includes: replacing the first keyword described in the behavior template with an identifier of that physical component; replacing the second keyword described in the behavior template with an identifier of that state; or replacing the third keyword described in the behavior template with one or more values output by that physical component in that state.

### (Supplementary Note 3)

The physical model generation apparatus according to supplementary note 1 or 2,
wherein the connection condition is defined by a combination of: whether or not an input port connected with a controller is working; whether or not an input port connected with the physical component other than a controller is working; and whether or not an output port connected with a controller is working.

### (Supplementary Note 4)

The physical model generation apparatus according to any one of supplementary notes 1 to 3,
wherein the state information is defined for each type of the physical components,
the acquisition of the state information including acquiring, for each of the plurality of the physical components described in the architecture information, the state information corresponding to the type of that physical component.

### (Supplementary Note 5)

The physical model generation apparatus according to any one of supplementary notes 1 to 4,
wherein the behavior template describes one or more behaviors of the physical components that are compromised and one or more behaviors of the physical components that are not compromised.

### (Supplementary Note 6)

A control method performed by a computer, comprising:
acquiring architecture information that describes a plurality of physical components included in a target control system, and one or more connections with another physical component for each of the plurality of the physical components;
acquiring, for each of the plurality of the physical components described in the architecture information, state information that describes one or more associations between a state of the physical component and one or more working connections that are the connections through which signals are transferred in the state corresponding thereto;
acquiring template information that describes a plurality of associations between a behavior template and a connection condition, the behavior template describing one or more behaviors that are common to the physical components whose working connections satisfy the connection condition corresponding thereto;
generating, for each of the plurality of the physical components described in the architecture information, behavior information that describes one or more behaviors of the physical component for each of the states of the physical component based on the architecture information, the state information, and the template information, thereby generating a physical model of the target control system that includes the behavior information of each of the plurality of the physical components included in the target control system.

### (Supplementary Note 7)

The control method according to supplementary note 6,
wherein the description of the behavior template includes: a first keyword to be replaced by an identifier of the physical component; the second keyword to be replaced by an identifier of the state of the physical component; or the third keyword to be replaced by one or more values output by the physical component, and
the generation of the behavior information for a physical component in a state includes: replacing the first keyword described in the behavior template with an identifier of that physical component; replacing the second keyword described in the behavior template with an identifier of that state; or replacing the third keyword described in the behavior template with one or more values output by that physical component in that state.

### (Supplementary Note 8)

The control method according to supplementary note 6 or 7,
wherein the connection condition is defined by a combination of: whether or not an input port connected with a controller is working; whether or not an input port connected with the physical component other than a controller is working; and whether or not an output port connected with a controller is working.

### (Supplementary Note 9)

The control method according to any one of supplementary notes 6 to 8,
wherein the state information is defined for each type of the physical components,
the acquisition of the state information including acquiring, for each of the plurality of the physical components described in the architecture information, the state information corresponding to the type of that physical component.

### (Supplementary Note 10)

The control method according to any one of supplementary notes 6 to 9,
wherein the behavior template describes one or more behaviors of the physical components that are compromised and one or more behaviors of the physical components that are not compromised.

### (Supplementary Note 11)

A computer-readable storage medium storing a program that causes a computer to execute:
acquiring architecture information that describes a plurality of physical components included in a target control system, and one or more connections with another physical component for each of the plurality of the physical components;
acquiring, for each of the plurality of the physical components described in the architecture information, state information that describes one or more associations between a state of the physical component and one or more working connections that are the connections through which signals are transferred in the state corresponding thereto;
acquiring template information that describes a plurality of associations between a behavior template and a connection condition, the behavior template describing one or more behaviors that are common to the physical components whose working connections satisfy the connection condition corresponding thereto;
generating, for each of the plurality of the physical components described in the architecture information, behavior information that describes one or more behaviors of the physical component for each of the states of the physical component based on the architecture information, the state information, and the template information, thereby generating a physical model of the target control system that includes the behavior information of each of the plurality of the physical components included in the target control system.

### (Supplementary Note 12)

The storage medium according to supplementary note 11,
wherein the description of the behavior template includes: a first keyword to be replaced by an identifier of the physical component; the second keyword to be replaced by an identifier of the state of the physical component; or the third keyword to be replaced by one or more values output by the physical component, and
the generation of the behavior information for a physical component in a state includes: replacing the first keyword described in the behavior template with an identifier of that physical component; replacing the second keyword described in the behavior template with an identifier of that state; or replacing the third keyword described in the behavior template with one or more values output by that physical component in that state.

### (Supplementary Note 13)

The storage medium according to supplementary note 11 or 12,
wherein the connection condition is defined by a combination of: whether or not an input port connected with a controller is working; whether or not an input port connected with the physical component other than a controller is working; and whether or not an output port connected with a controller is working.

### (Supplementary Note 14)

The storage medium according to any one of supplementary notes 11 to 13,
wherein the state information is defined for each type of the physical components,
the acquisition of the state information including acquiring, for each of the plurality of the physical components described in the architecture information, the state information corresponding to the type of that physical component.

### (Supplementary Note 15)

The storage medium according to any one of supplementary notes 11 to 14,
wherein the behavior template describes one or more behaviors of the physical components that are compromised and one or more behaviors of the physical components that are not compromised.

### REFERENCE SIGNS LIST

10 architecture information
20 state information
30 template information
40 physical model
42 behavior information
50 target control system
52 physical component
54 connection
100 table
102 identifier
104 type
106 connection
108 port
110 direction
112 component
200 table
202 identifier
204 input port
206 output port
208 values
210 initial value
300 table
302 identifier
304 condition C1
306 condition C2
308 condition C3
400 table
402 connection condition
404 behavior template
500 table
502 component identifier
504 type identifier
506 behavior information
508 state identifier
510 matched condition
512 behaviors
600 table
602 identifier
604 type
606 connection
608 port
610 direction
612 component
700 table
702 identifier
704 input port
706 output port
708 values
710 initial value
800 table
802 identifier
804 input port
806 output port
808 values
810 initial value
900 table
902 component identifier
904 type identifier
906 behavior information
908 state identifier
910 matched condition
912 behaviors
1000 computer
1020 bus
1040 processor
1060 memory
1080 storage device
1100 input/output interface
1120 network interface
2000 physical model generation apparatus
2020 acquisition unit
2040 generation unit
2040 generation unit

What is claimed is:

1. A physical model generation apparatus comprising:
at least one memory that is configured to store instructions; and
at least one processor that is configured to execute the instructions to:
acquire architecture information that describes a plurality of physical components included in a target control system, and one or more connections with another physical component for each of the plurality of the physical components;
acquire, for each of the plurality of the physical components described in the architecture information, state information that describes one or more associations between a state of the physical component and one or more working connections that are the connections through which signals are transferred in the state corresponding thereto;
acquire template information that describes a plurality of associations between a behavior template and a connection condition, the behavior template describing one or more behaviors that are common to the physical components whose working connections satisfy the connection condition corresponding thereto;
generate, for each of the plurality of the physical components described in the architecture information, behavior information that describes one or more behaviors of the physical component for each of the states of the physical component based on the architecture information, the state information, and the template information, thereby generating a physical model of the target control system that includes the behavior information of each of the plurality of the physical components included in the target control system.

2. The physical model generation apparatus according to claim 1,
wherein the description of the behavior template includes: a first keyword to be replaced by an identifier of the physical component; the second keyword to be replaced by an identifier of the state of the physical component; or the third keyword to be replaced by one or more values output by the physical component, and
the generation of the behavior information for a physical component in a state includes: replacing the first keyword described in the behavior template with an identifier of that physical component; replacing the second keyword described in the behavior template with an identifier of that state; or replacing the third keyword described in the behavior template with one or more values output by that physical component in that state.

3. The physical model generation apparatus according to claim 1,
wherein the connection condition is defined by a combination of: whether or not an input port connected with a controller is working; whether or not an input port connected with the physical component other than a controller is working; and whether or not an output port connected with a controller is working.

4. The physical model generation apparatus according to claim 1,
wherein the state information is defined for each type of the physical components,
the acquisition of the state information including acquiring, for each of the plurality of the physical components described in the architecture information, the state information corresponding to the type of that physical component.

5. The physical model generation apparatus according to claim 1,
wherein the behavior template describes one or more behaviors of the physical components that are compromised and one or more behaviors of the physical components that are not compromised.

6. A control method performed by a computer, comprising:
acquiring architecture information that describes a plurality of physical components included in a target control system, and one or more connections with another physical component for each of the plurality of the physical components;
acquiring, for each of the plurality of the physical components described in the architecture information, state information that describes one or more associations between a state of the physical component and one or more working connections that are the connections through which signals are transferred in the state corresponding thereto;
acquiring template information that describes a plurality of associations between a behavior template and a connection condition, the behavior template describing one or more behaviors that are common to the physical components whose working connections satisfy the connection condition corresponding thereto;
generating, for each of the plurality of the physical components described in the architecture information, behavior information that describes one or more behaviors of the physical component for each of the states of the physical component based on the architecture information, the state information, and the template information, thereby generating a physical model of the target control system that includes the behavior information of each of the plurality of the physical components included in the target control system.

7. The control method according to claim 6,
wherein the description of the behavior template includes: a first keyword to be replaced by an identifier of the physical component; the second keyword to be replaced by an identifier of the state of the physical component; or the third keyword to be replaced by one or more values output by the physical component, and
the generation of the behavior information for a physical component in a state includes: replacing the first keyword described in the behavior template with an identifier of that physical component; replacing the second keyword described in the behavior template with an identifier of that state; or replacing the third keyword described in the behavior template with one or more values output by that physical component in that state.

8. The control method according to claim 6,
wherein the connection condition is defined by a combination of: whether or not an input port connected with a controller is working; whether or not an input port connected with the physical component other than a controller is working; and whether or not an output port connected with a controller is working.

9. The control method according to claim 6,
wherein the state information is defined for each type of the physical components,
the acquisition of the state information including acquiring, for each of the plurality of the physical components described in the architecture information, the state information corresponding to the type of that physical component.

10. The control method according to claim 6,
wherein the behavior template describes one or more behaviors of the physical components that are compromised and one or more behaviors of the physical components that are not compromised.

11. A non-transitory computer-readable storage medium storing a program that causes a computer to execute:
acquiring architecture information that describes a plurality of physical components included in a target control system, and one or more connections with another physical component for each of the plurality of the physical components;
acquiring, for each of the plurality of the physical components described in the architecture information, state information that describes one or more associations between a state of the physical component and one or more working connections that are the connections through which signals are transferred in the state corresponding thereto;
acquiring template information that describes a plurality of associations between a behavior template and a connection condition, the behavior template describing one or more behaviors that are common to the physical components whose working connections satisfy the connection condition corresponding thereto;
generating, for each of the plurality of the physical components described in the architecture information, behavior information that describes one or more behaviors of the physical component for each of the states of the physical component based on the architecture information, the state information, and the template information, thereby generating a physical model of the target control system that includes the behavior information of each of the plurality of the physical components included in the target control system.

12. The storage medium according to claim 11,
wherein the description of the behavior template includes: a first keyword to be replaced by an identifier of the physical component; the second keyword to be replaced by an identifier of the state of the physical component; or the third keyword to be replaced by one or more values output by the physical component, and
the generation of the behavior information for a physical component in a state includes: replacing the first keyword described in the behavior template with an identifier of that physical component; replacing the second keyword described in the behavior template with an identifier of that state; or replacing the third keyword described in the behavior template with one or more values output by that physical component in that state.

13. The storage medium according to claim 11,
wherein the connection condition is defined by a combination of: whether or not an input port connected with a controller is working; whether or not an input port connected with the physical component other than a controller is working; and whether or not an output port connected with a controller is working.

14. The storage medium according to claim 11,
wherein the state information is defined for each type of the physical components,
the acquisition of the state information including acquiring, for each of the plurality of the physical components described in the architecture information, the state information corresponding to the type of that physical component.

15. The storage medium according to claim 11,
wherein the behavior template describes one or more behaviors of the physical components that are compromised and one or more behaviors of the physical components that are not compromised.
